(19) United States
(12) Patent Application Publication
(10) Pub. No.: US 2026/0082560 A1
(43) Pub. Date: Mar. 19, 2026

(54) SEMICONDUCTOR MEMORY DEVICE AND MANUFACTURING METHOD OF THE SAME

(71) Applicant: Kioxia Corporation, Tokyo (JP)

(72) Inventors: Yohei SUGAWARA, Yokkaichi Mie (JP); Masaki NOGUCHI, Yokkaichi Mie (JP)

(21) Appl. No.: 19/070,415

(22) Filed: Mar. 4, 2025

(30) Foreign Application Priority Data
Sep. 13, 2024 (JP) 2024-159616

(51) Int. Cl. H10B 43/27; H01L 23/00; H01L 25/18; H10B 43/10; H10B 43/35; H10B 80/00; H10D 30/01; H10D 30/69; H10D 64/01; H10D 64/68; H10D 80/20

(52) U.S. Cl. CPC H10B 43/27; H10B 43/10; H10B 43/35; H10B 80/00; H10D 30/0413; H10D 30/693; H10D 64/037; H10D 64/685; H10D 64/691; H10D 80/251; H10W 90/00; H10W 90/792

(57) ABSTRACT

According to one embodiment, a semiconductor memory device includes a stacked body in which a plurality of electrode films and a plurality of first insulating films are alternately stacked in a first direction, a columnar body that penetrates the stacked body in the first direction, an aluminum oxide film provided between the columnar body and each of the electrode films, and a first tetravalent metal oxide provided at an interface between the columnar body and the aluminum oxide film.

### CROSS-REFERENCE TO RELATED APPLICATION(S)

This application is based upon and claims the benefit of priority from Japanese Patent Application No. 2024-159616, filed Sep. 13, 2024, the entire contents of which are incorporated herein by reference.

### FIELD

Embodiments described herein relate generally to a semiconductor memory device and a manufacturing method of the same.

### BACKGROUND

A semiconductor memory device such as a NAND flash memory may include a three-dimensional memory cell array in which a plurality of memory cells are three-dimensionally arranged. In such a three-dimensional memory cell array, a block insulating film is provided between a word line and a charge storage layer to prevent back tunneling of charges from the word line to the charge storage layer. In such a semiconductor memory device, it is desired to improve data retention property in the charge storage layer, increase write saturation, and reduce erase saturation.

### BRIEF DESCRIPTION OF THE DRAWINGS

FIG. 1 is a cross-sectional view illustrating an example of a configuration of a semiconductor memory device according to the present embodiment.

FIG. 2 is a plan view of a stacked body provided in the semiconductor memory device.

FIG. 3 is a cross-sectional view illustrating an example of a memory cell having a three-dimensional structure.

FIG. 4 is another cross-sectional view illustrating an example of the memory cell having the three-dimensional structure.

FIG. 5 is a cross-sectional view illustrating a part of the memory cell in FIG. 3 in more detail.

FIG. 6 is a cross-sectional view illustrating a first example layer configuration between a charge trapping film and an electrode film. ;

FIG. 7 is a cross-sectional view illustrating a second example layer configuration between the charge trapping film and the electrode film.

FIG. 8 is a cross-sectional view illustrating a third example layer configuration between the charge trapping film and the electrode film.

FIG. 9 is a cross-sectional view illustrating a fourth example layer configuration between the charge trapping film and the electrode film.

FIG. 10 is a cross-sectional view illustrating a baseline example layer configuration between the charge trapping film and the electrode film.

FIG. 11 is a graph illustrating data retention property of the different examples.

FIG. 12 is a graph illustrating write saturation voltages of the different examples.

FIG. 13 is a cross-sectional view illustrating an example layer configuration in which metal oxide is added to the configuration of FIG. 6.

FIG. 14 is a cross-sectional view illustrating an example layer configuration in which metal oxide is added to the configuration of FIG. 9.

FIG. 15 is a graph illustrating erase saturation voltages of the different examples.

FIGS. 16-21 are cross-sectional views illustrating an example of a process of manufacturing the semiconductor memory device according to the present embodiment.

### DETAILED DESCRIPTION

Embodiments provide a semiconductor memory device capable of improving data retention property, increasing write saturation, and reducing erase saturation, and a method of manufacturing the same.

In general, according to one embodiment, a semiconductor memory device according to the present embodiment includes a stacked body in which a plurality of electrode films and a plurality of first insulating films are alternately stacked in a first direction, a columnar body that penetrates the stacked body in the first direction, an aluminum oxide film provided between the columnar body and each of the electrode films, and a first tetravalent metal oxide provided at an interface between the columnar body and the aluminum oxide film.

Hereinafter, embodiments of the present disclosure will be described with reference to the accompanying drawings. The described embodiments do not limit the scope of the present disclosure. The drawings are schematic or conceptual. In the specification and the drawings, the same elements are represented by the same reference signs.

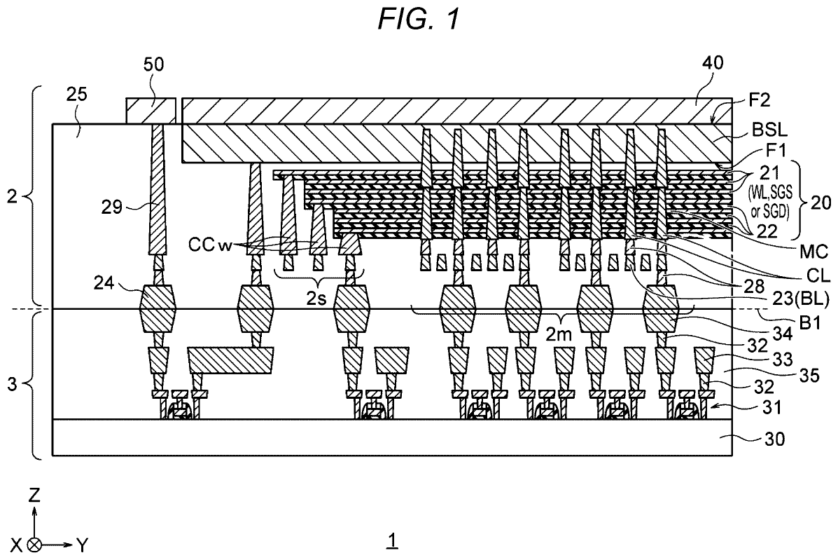

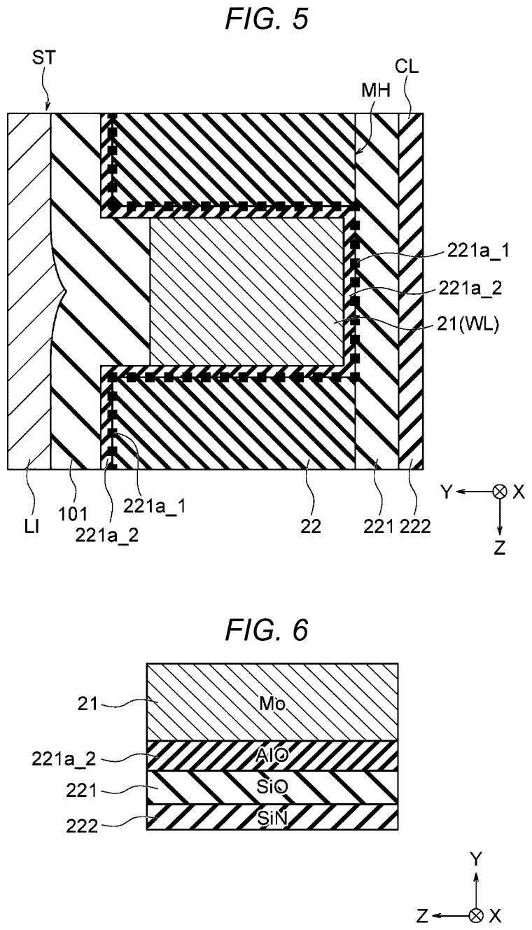

FIG. 1 is a cross-sectional view illustrating an example of a configuration of a semiconductor memory device 1 according to the present embodiment. Hereinafter, a stacking direction of a stacked body 20 is defined as a Z direction. A direction that intersects the Z direction, for example, a direction perpendicular to the Z direction is defined as a Y direction. A direction that intersects each of the Z direction and the Y direction, for example, a direction perpendicular to each of the Z direction and the Y direction is defined as an X direction. FIG. 1 shows semiconductor memory device 1 assuming that a +Z direction is an upward direction. The cross-sectional views of FIG. 5 and subsequent figures may depict array chips where a −Z direction or a +Y direction is the upward direction. In the present specification, the ±Z direction is an example of a first direction.

The semiconductor memory device 1 includes an array chip 2 including a memory cell array and a CMOS chip 3 including a CMOS circuit. The array chip 2 and the CMOS chip 3 are bonded at a bonding surface B1, and are electrically connected to each other via wirings bonded at the bonding surface B1. FIG. 1 shows a state where the array chip 2 is provided on the CMOS chip 3.

The CMOS chip 3 includes a substrate 30, transistors 31, vias 32, wirings 33 and 34, and an interlayer insulating film 35.

The substrate 30 is, for example, a semiconductor substrate such as a silicon substrate. The transistor 31 is an N-type metal oxide semiconductor field effect transistor (MOSFET) or a P-type MOSFET provided on the substrate 30. The transistors 31 make up, for example, a complementary MOS (CMOS) circuit that controls a memory cell array 2m of the array chip 2. A plurality of transistors 31 are parts of logic circuits such as a sense amplifier, a row decoder, and a column decoder. Semiconductor elements such as resistor elements and capacitor elements other than the transistors 31 may be formed on the substrate 30.

The vias 32 electrically connect the transistors 31 to the wiring 33, or the wiring 33 to the wiring 34. The wirings 33 and 34 make up a multilayer wiring structure in the interlayer insulating film 35. The wiring 34 is embedded in the interlayer insulating film 35 and is exposed to be coplanar with a surface of the interlayer insulating film 35. The wirings 33 and 34 are electrically connected to the transistors 31 and the like. The vias 32 and the wirings 33 and 34 are made of metal such as copper or tungsten. The interlayer insulating film 35 covers and protects the transistors 31, the vias 32, and the wirings 33 and 34. The interlayer insulating film 35 employs an insulating film such as a silicon oxide film.

The array chip 2 includes a stacked body 20, columnar bodies CL, a source layer BSL, a metal layer 40, contact plugs CCw, a contact plug 29, a bonding pad 50, wirings 23 and 24, vias 28, and an interlayer insulating film 25.

The stacked body 20 is provided above the transistor 31 and is located in the +Z direction of the substrate 30. The stacked body 20 is formed by alternately stacking a plurality of electrode films 21 and a plurality of insulating films 22 along the Z direction. The stacked body 20 and the columnar bodies CL configure a memory cell array. The electrode film 21 employs conductive metal such as tungsten. The insulating film 22 employs, for example, a silicon oxide film or the like. The insulating films 22 insulate the electrode films 21 from each other. That is, the plurality of electrode films 21 are stacked to be insulated from each other. The number of stacked electrode films 21 and the number of stacked insulating films 22 are freely selected. The insulating film 22 may be, for example, a porous insulating film or an air gap.

One or a plurality of electrode films 21 at each of an upper end and a lower end of the stacked body 20 in the Z direction respectively function as a source-side select gate SGS and a drain-side select gate SGD. The electrode films 21 between the source-side select gate SGS and the drain-side select gate SGD functions as word lines WL. Each word line WL is a gate electrode of a memory cell MC. The source-side select gate SGS is a gate electrode of a source-side select transistor. The drain-side select gate SGD is a gate electrode of a drain-side select transistor. The source-side select gate SGS is provided in an upper region of the stacked body 20. The drain-side select gate SGD is provided in a lower region of the stacked body 20. The upper region refers to a region of the stacked body 20 farther from the CMOS chip 3 (closer to the metal layer 40), and the lower region refers to a region of the stacked body 20 closer to the CMOS chip 3.

The semiconductor memory device 1 includes a plurality of memory cells MC connected in series between the source-side select transistor and the drain-side select transistor. A structure in which the source-side select transistor, the memory cells MC, and the drain-side select transistor are connected in series is referred to as a “memory string” or a “NAND string”. For example, the memory string is connected to a bit line BL through the via 28. The bit line BL is the wiring 23 provided under the stacked body 20 and extending in the X direction. Therefore, hereinafter, the bit line BL is also referred to as a bit line 23.

The stacked body 20 includes a plurality of columnar bodies CL. The columnar bodies CL are provided in the stacked body 20, extend to penetrate the stacked body 20 in the stacking direction (Z direction) of the stacked body 20, and are provided in a range from the vias 28, that are connected to the bit lines 23, to the source layer BSL. An internal structure of the columnar bodies CL will be described later. FIG. 1 shows a case where the columnar bodies CL are formed in two stages in the Z direction. However, the columnar body CL may be formed in three or more stages.

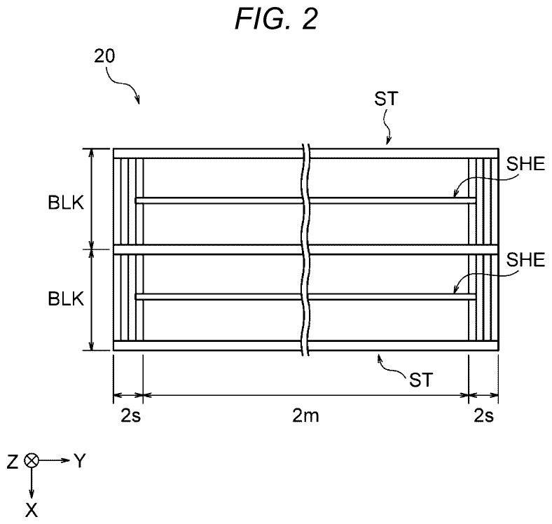

Although not illustrated in FIG. 1, a plurality of slits ST (refer to FIG. 2) are provided in the stacked body 20. The slits ST extend in the Y direction and penetrate the stacked body 20 in the stacking direction (Z direction) of the stacked body 20. The slits ST are filled with an insulating film such as a silicon oxide film, and the insulating film is formed in a plate shape. The slits ST electrically divides the electrode film 21 of the stacked body 20. Alternatively, an inner wall of the slit ST may be covered with an insulating film such as a silicon oxide film, and a conductive material may be embedded in the insulating film. Here, the conductive material may also function as a source wiring that reaches the source layer BSL.

The source layer BSL is provided on the stacked body 20. A memory cell array 2m formed in the stacked body is provided on a face F1 side of the source layer BSL, and a metal layer 40 is provided on a face F2 opposite to the face F1. The source layer BSL is connected in common to one ends of the plurality of columnar bodies CL, and applies a common source voltage to the plurality of columnar bodies CL in the same memory cell array 2m. That is, the source layer BSL functions as a common source electrode of the memory cell array 2m. The source layer BSL employs a conductive material such as doped polysilicon. The metal layer 40 employs a metal material having a lower resistance than the source layer BSL, such as copper, aluminum, or tungsten.

Meanwhile, the bonding pad 50 is provided in an area above the face F2 of the source layer BSL where the source layer BSL is not provided. The bonding pad 50 is connected to a metal wire or the like (not illustrated in the drawing) and is supplied with electric power or receives a signal from the outside of the semiconductor memory device 1. The bonding pad 50 is connected to one end of the contact plug 29 in the Z direction. The bonding pad 50 is connected to the transistor 31 of the CMOS chip 3 via the contact plug 29, the wiring 24, and the wiring 34. An external power supply is supplied from the bonding pad 50 to the transistor 31. Alternatively, a signal may be supplied to the transistor 31 via the bonding pad 50.

The contact plugs CCw are provided in a peripheral portion of the stacked body 20 and extend in the Z direction in the interlayer insulating film 25. The contact plugs CCw are electrically connected between the electrode films 21 (that make up the word lines WL) and the wiring 24. The contact plugs CCw are provided in a staircase portion 2s in which the electrode films 21 are formed in a staircase shape at ends of the stacked body 20, and are electrically connected to different electrode films 21. Each contact plug CCw is provided to transmit a word line voltage from the CMOS chip 3 to one electrode film 21. The contact plug CCw employs metal such as copper or tungsten.

The contact plug 29 is provided on the peripheral portion of the stacked body 20 and extends in the Z direction in the interlayer insulating film 25. The contact plug 29 is provided at least in a range from a lower side of the stacked body 20 to an upper side of the stacked body 20.

The contact plug 29 is electrically connected between the bonding pad 50 and the wiring 24. The contact plug 29 is used for power supply or a signal from the bonding pad 50 to the array chip 2 or the CMOS chip 3. The contact plug 29 employs metal such as copper or tungsten. The power supply is, for example, a power supply voltage VDD or a reference voltage (for example, a ground voltage) VSS lower than the power supply voltage VDD. The signal may be a control signal from the outside, or may be a data signal containing write data or read data.

In the present embodiment, the array chip 2 and the CMOS chip 3 are separately formed and bonded to each other on the bonding surface B1. Therefore, the array chip 2 does not include the transistors 31. Further, the CMOS chip 3 does not include the stacked body 20.

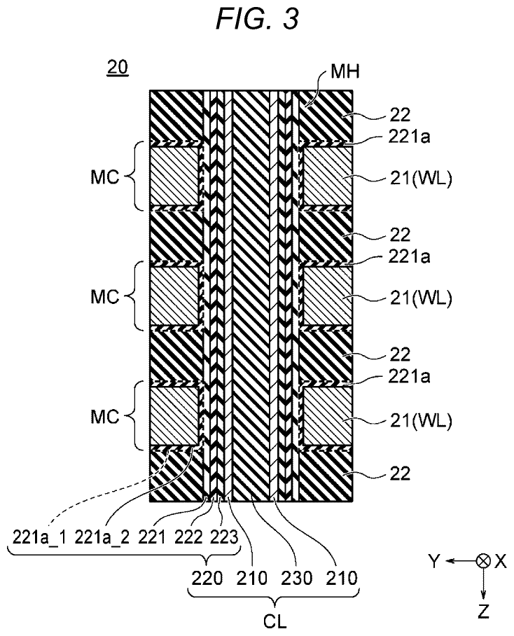

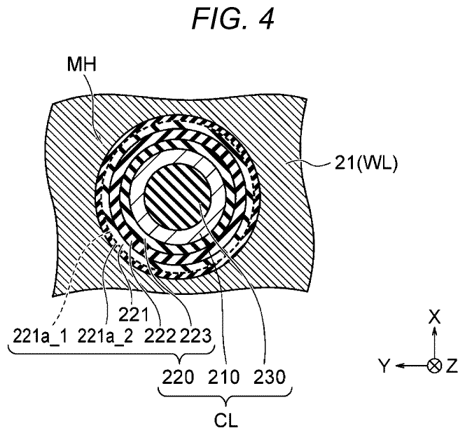

The vias 28, the wiring 23, and the wiring 24 are provided under the stacked body 20. The wirings 23 and 24 are embedded in the interlayer insulating film 25. The wiring 24 is exposed to be coplanar with a surface of the interlayer insulating film 25. The wirings 23 and 24 are electrically connected to the semiconductor bodies of the columnar bodies CL (210 in FIGS. 3 and 4), and the like. The via 28, the wiring 23, and the wiring 24 each employ metal such as copper or tungsten. The interlayer insulating film 25 covers and protects the stacked body 20, the vias 28, the wiring 23, and the wiring 24. The interlayer insulating film 25 employs an insulating film such as a silicon oxide film.

The interlayer insulating film 25 and the interlayer insulating film 35 are bonded to each other on the bonding surface B1. Therefore, the wiring 24 and the wiring 34 are bonded to each other on the bonding surface B1 to be substantially coplanar. Thereby, the array chip 2 and the CMOS chip 3 are electrically connected to each other via the wiring 24 and the wiring 34.

FIG. 2 is a plan view of the stacked body 20. The stacked body 20 includes the staircase portion 2s and the memory cell array 2m. The staircase portion 2s is provided, for example, at the ends of the stacked body 20. The memory cell array 2m is interposed between or surrounded by the staircase portion 2s. The slits ST extend from the staircase portion 2s at one end of the stacked body 20 across the memory cell array 2m to the staircase portion 2s at the other end of the stacked body 20. Slits SHE extend in the Y direction at least as much as the memory cell array 2m. The slit SHE is shorter than the slit ST in the Z direction and extends substantially parallel to the slit ST. The slits SHE electrically divide the electrode films 21 on a lower region side of the stacked body 20 for each drain-side select gate SGD. The slit SHE employs an insulating film such as a silicon oxide film. The slit ST may include a source wiring electrically connected to the source layer BSL while being electrically separated from the electrode films 21 of the stacked body 20.

A part of the stacked body 20 interposed between two slits ST illustrated in FIG. 2 is referred to as a block BLK. The block BLK is configured as, for example, a minimum unit of data erasing. The slits SHE are provided in the block BLK. The stacked body 20 between the slit ST and the slit SHE is referred to as a finger. The drain-side select gate SGD is separate for each finger. Therefore, when writing and reading data, one finger in the block BLK can be set to a selected state through the drain-side select gate SGD.

Each of FIGS. 3 and 4 is a cross-sectional view illustrating a memory cell having a three-dimensional structure. The plurality of columnar bodies CL are provided in memory holes MH in the stacked body 20. Each columnar body CL penetrates the stacked body 20 from one end of the stacked body 20 along the Z direction and is provided in a range across inside of the stacked body 20 and inside of the source layer BSL. Each of the plurality of columnar bodies CL includes a semiconductor body 210, a memory film 220, and a core layer 230. The columnar body CL includes the core layer 230 provided at a center thereof, the semiconductor body (semiconductor layer) 210 provided around the core layer 230, and the memory film 220 provided around the semiconductor body 210. In the stacked body 20, the semiconductor body 210 extends in the stacked body 20 in the Z direction along the memory hole MH and penetrates the stacked body 20. The semiconductor body 210 is electrically connected to the source layer BSL. The memory film 220 is provided between the semiconductor body 210 and the electrode films 21, and includes a cover insulating film 221, a charge trapping film 222, and a tunnel insulating film 223. A plurality of columnar bodies CL selected from each finger are connected in common to one bit line 23 through the vias 28 in FIG. 1. Each of the columnar bodies CL is provided, for example, in a region of the memory cell array 2m.

A metal oxide 221a_1 and a block insulating film 221a_2 are provided between the columnar body CL and each electrode film 21. The metal oxide 221a_1 and the block insulating film 221a_2 cover each electrode film 21 (word line WL). Therefore, the metal oxide 221a_1 and the block insulating film 221a_2 are also provided between each electrode film 21 and the insulating film 22. The metal oxide 221a_1 is provided at an interface between the block insulating film 221a_2 and the cover insulating film 221. The metal oxide 221a_1 is made of a tetravalent metal oxide, and may be made of, for example, one of TiO₂, ZrO₂, HfO₂, and RfO₂. The metal oxide 221a_1 is a metal oxide having a higher relative dielectric constant than a silicon oxide film. The block insulating film 221a_2 is made of, for example, aluminum oxide. The block insulating film 221a_2 prevents back tunneling of charges from the electrode film 21 to the memory film 220. The metal oxide 221a_1 is able to improve data retention property and erase saturation voltage, and to prevent deterioration of write saturation voltage. The metal oxide 221a_1 will be described in more detail later. The metal oxide 221a_1 and the block insulating film 221a_2 configure a part of the memory film 220.

As illustrated in FIG. 4, a shape of the memory hole MH in an XY plane is, for example, a circle or an ellipse. Accordingly, a shape of the columnar body CL in the XY plane is, for example, a circle or an ellipse.

The semiconductor body 210 has, for example, a bottomed cylindrical shape. The semiconductor body 210 employs, for example, polysilicon. The semiconductor body 210 is, for example, undoped silicon. The semiconductor body 210 may be p-type silicon. The semiconductor body 210 is configured as a channel for each of the drain-side select transistor, the memory cells MC, and the source-side select transistor. That is, the plurality of memory cells MC each include a storage region between the semiconductor body 210 and the electrode film 21 as the word line WL, and are stacked in the Z direction. One ends of the plurality of semiconductor bodies 210 in the same memory cell array 2m are electrically connected in common to the source layer BSL.

As illustrated in FIG. 3, the memory film 220 includes, for example, the cover insulating film 221, the charge trapping film 222, the tunnel insulating film 223, the metal oxide 221a_1, and the block insulating film 221a_2. A part of the memory film 220 other than the metal oxide 221a_1 and the block insulating film 221a_2 is provided as a part of the columnar body CL between an inner wall (the stacked body 20) of the memory hole MH and the semiconductor body 210. Shapes of the cover insulating film 221, the charge trapping film 222, and the tunnel insulating film 223 are, for example, cylindrical. The cover insulating film 221, the charge trapping film 222, and the tunnel insulating film 223 each extend in the Z direction.

The cover insulating film 221 is provided between the semiconductor body 210 and the stacked body 20 that includes the electrode films 21 and the insulating film 22. In particular, the cover insulating film 221 is provided between the insulating film 22 and the charge trapping film 222, and between the block insulating film 221a_2 (or the metal oxide 221a_1) and the charge trapping film 222. The cover insulating film 221 contains, for example, silicon oxide. The cover insulating film 221 protects the charge trapping film 222 from being etched when the sacrificial films are replaced by the electrode films 21 (during the replacement step).

The charge trapping film 222 is provided between the cover insulating film 221 and the semiconductor body 210. In particular the charge trapping film 222 is provided between the cover insulating film 221 and the tunnel insulating film 223. The charge trapping film 222 contains, for example, silicon nitride, and includes trap sites for trapping charges. A part of the charge trapping film 222 interposed between the electrode film 21 as the word line WL and the semiconductor body 210 configures a storage area of the memory cell MC as a charge trapping portion. A threshold voltage of the memory cell MC changes depending on whether charge is trapped in the charge trapping portion or an amount of charge trapped in the charge trapping portion. Thereby, the memory cell MC stores information.

The tunnel insulating film 223 is provided between the semiconductor body 210 and the charge trapping film 222. The tunnel insulating film 223 contains, for example, silicon oxide, or silicon oxide and silicon nitride. The tunnel insulating film 223 is a potential barrier between the semiconductor body 210 and the charge trapping film 222. For example, when electrons are injected from the semiconductor body 210 to the charge trapping film 222 (e.g., during a write operation) and when holes are injected from the semiconductor body 210 to the charge trapping film 222 (e.g., during an erase operation), the electrons and the holes each pass through the potential barrier of the tunnel insulating film 223. This electron behavior is referred to as tunneling.

The core layer 230 fills an internal space of the cylindrical semiconductor body 210. The core layer 230 has, for example, a columnar shape. The core layer 230 contains, for example, silicon oxide and has insulating property.

FIG. 5 is a cross-sectional view illustrating a part of the memory cell of FIG. 3 in more detail. The charge trapping film 222 and the cover insulating film 221 in the columnar body CL in the memory hole MH are illustrated in the drawing. The block insulating film (aluminum oxide film) 221a_2 is provided between the cover insulating film 221 of the columnar body CL and the electrode film 21, and between the insulating film 22 and the electrode film 21. The metal oxide 221a_1 is provided at an interface between the cover insulating film 221 of the columnar body CL and the block insulating film 221a_2, and at an interface between the insulating film 22 and the block insulating film 221a_2.

A concentration of the metal oxide 221a_1 is maximum at the interface between the cover insulating film 221 and the block insulating film 221a_2, and at the interface between the insulating film 22 and the block insulating film 221a_2. The concentration of the metal oxide 221a_1 is lower at a position closer to the interface between the electrode film 21 and the block insulating film 221a_2 than the interface between the cover insulating film 221 and the block insulating film 221a_2 or between the insulating film 22 and the block insulating film 221a_2. The concentration of the metal oxide 221a_1 is lower at a position closer to the cover insulating film 221 of the columnar body CL than at a position closer to the block insulating film 221a_2. The concentration of the metal oxide 221a_1 is lower at a position closer to the insulating film 22 than at a position closer to the block insulating film 221a_2. That is, the concentration of the metal oxide 221a_1 gradually decreases from the interface between the cover insulating film 221 and the block insulating film 221a_2 or between the insulating film 22 and the block insulating film 221a_2. The metal oxide 221a_1 is provided in a range of 0.1 nm to 0.3 nm in a direction intersecting with (for example, perpendicular to) the interface between the block insulating film 221a_2 and the cover insulating film 221. The metal oxide 221a_1 may be provided as a film, or may be detected as a component not recognized as a film.

Here, a description will be given of a configuration of the cover insulating film 221, the metal oxide 221a_1, and the block insulating film 221a_2 between the charge trapping film 222 and the electrode film 21.

FIGS. 6 to 10 are cross-sectional views illustrating examples of the configuration between the charge trapping film 222 and the electrode film 21.

In the example of FIG. 6, a stacked film including the cover insulating film 221 and the block insulating film 221a_2 is provided between the charge trapping film 222 and the electrode film 21. A film thickness of the aluminum oxide film of the block insulating film 221a_2 is, for example, about 2.7 nm. In the examples of FIGS. 6 to 9, the electrode film 21 is made of molybdenum. Here, a titanium nitride film (not illustrated in the drawing) as a barrier film is not provided between the block insulating film 221a_2 and the electrode film 21.

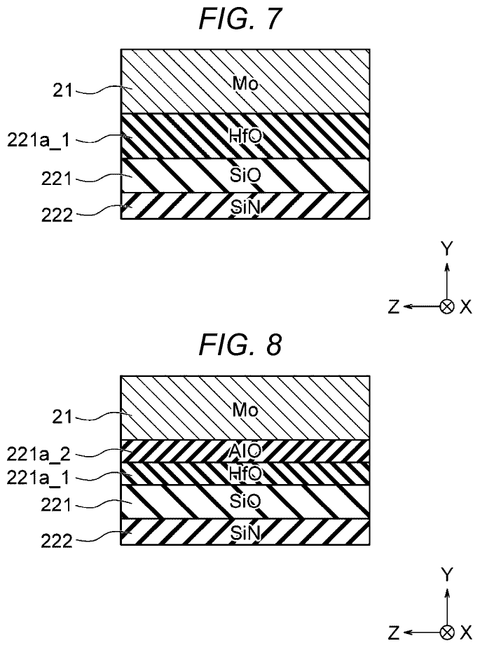

In the example of FIG. 7, a stacked film including the cover insulating film 221 and the metal oxide 221a_1 is provided between the charge trapping film 222 and the electrode film 21. In the example of FIG. 7, instead of the block insulating film 221a_2, the metal oxide 221a_1 is provided between the cover insulating film 221 and the electrode film 21. The metal oxide 221a_1 is, for example, hafnium oxide (HfO₂). A film thickness of the metal oxide 221a_1 is, for example, 5 nm, and the metal oxide 221a_1 can be recognized as a film.

In the example of FIG. 8, a stacked film including the cover insulating film 221, the metal oxide 221a_1, and the block insulating film 221a_2 is provided between the charge trapping film 222 and the electrode film 21. In the example of FIG. 8, the block insulating film 221a_2 and the metal oxide 221a_1 are provided. The metal oxide 221a_1 is provided between the cover insulating film 221 and the aluminum oxide film of the block insulating film 221a_2. The metal oxide 221a_1 is, for example, hafnium oxide (HfO₂). A film thickness of the aluminum oxide film of the block insulating film 221a_2 is, for example, about 2.7 nm. A film thickness of the metal oxide 221a_1 is, for example, 1 nm, and the metal oxide 221a_1 can be recognized as a film.

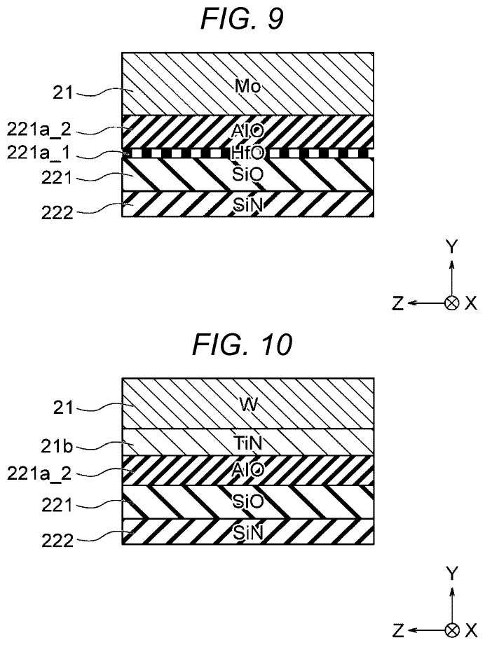

In the example of FIG. 9, similar to the configuration of FIG. 8, a stacked film including the cover insulating film 221, the metal oxide 221a_1, and the block insulating film 221a_2 is provided between the charge trapping film 222 and the electrode film 21. A film thickness of the aluminum oxide film of the block insulating film 221a_2 may be, for example, about 2.7 nm. Meanwhile, a film thickness of the metal oxide 221a_1 is, for example, 0.1 nm or less, and the metal oxide 221a_1 is barely recognizable as a film. The metal oxide 221a_1 can be detected as a component of hafnium oxide (HfO₂) detected at the interface between the cover insulating film 221 and the block insulating film 221a_2.

FIG. 10 is a cross-sectional view illustrating an example of the configuration in which the electrode film 21 is made of tungsten. In the example of FIG. 10, a stacked film including the cover insulating film 221, the block insulating film 221a_2, and a barrier film 21b is provided between the charge trapping film 222 and the electrode film 21. Here, the barrier film 21b is provided between the aluminum oxide film of the block insulating film 221a_2 and tungsten of the electrode film 21. The barrier film 21b is, for example, a titanium nitride film. The barrier film 21b is provided to improve adhesion between the aluminum oxide film of the block insulating film 221a_2 and tungsten of the electrode film 21. Other configuration of FIG. 10 is the same as the configuration of FIG. 6. Therefore, in the present example, the metal oxide 221a_1 is not provided.

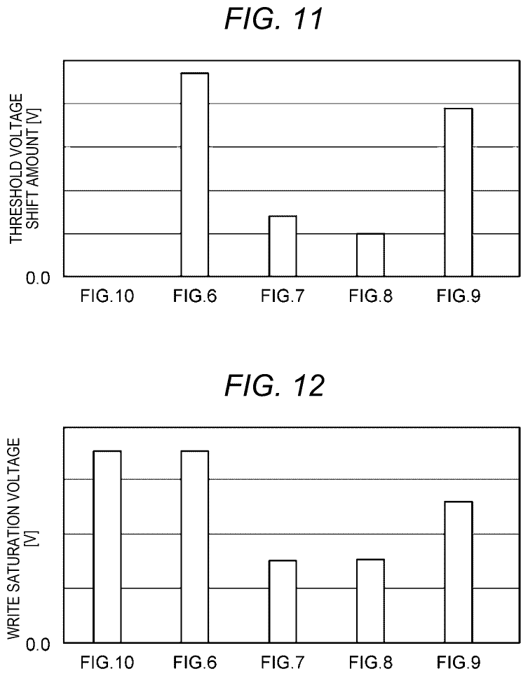

FIG. 11 is a graph illustrating shift amounts of threshold voltage in a memory cell, which is representative of its data retention property. A vertical axis of the graph indicates the shift amount (voltage) of the threshold voltage when the configuration of FIG. 10 is used as a reference. That is, the shift amount of the threshold voltage in the configuration of FIG. 10 is subtracted from the shift amount of the threshold voltage in each configuration. A horizontal axis indicates each configuration of FIGS. 6 to 9. The shift amount of the threshold voltage indicates a change in the data retention property of the memory cell MC that holds data after heating the memory cell MC by, for example, 240 degrees to 250 degrees. Therefore, when the shift amount of the threshold voltage is small, it is determined that the data retention property is fine, and a small shift amount of the threshold voltage is preferable.

In the configuration of FIG. 6, the aluminum oxide film of the block insulating film 221a_2 tends to allow oxygen atoms to pass from molybdenum (Mo) to the cover insulating film 221. As a result, molybdenum (Mo) tends to change into a molybdenum oxide film (MoOₓ) by exposure to source gas or air. The oxygen atoms generate OH⁺ with hydrogen atoms generated in hydrogen annealing in a subsequent process. OH⁺reacts with the silicon oxide film of the cover insulating film 221 to cause defects. The defects in the cover insulating film 221 tends to allow electrons in the charge trapping film 222 to pass to the electrode film 21. As a result, the shift amount of the threshold voltage of the memory cell MC is relatively large.

In the configuration of FIG. 7, hafnium oxide of the metal oxide 221a_1 tends to not allow oxygen atoms to pass through even when hafnium oxide is heated. Therefore, the cover insulating film 221 is unlikely to allow oxygen atoms to pass through, preventing generation of OH⁺. That is, occurrence of defects in the cover insulating film 221 is suppressed. As a result, the shift amount of the threshold voltage of the memory cell MC having the configuration of FIG. 7 is less than the shift amount of the threshold voltage of the memory cell MC having the configuration of FIG. 6.

In the configuration of FIG. 8, both hafnium oxide of the metal oxide 221a_1 and the aluminum oxide film of the block insulating film 221a_2 are provided. Hafnium oxide of the metal oxide 221a_1 is unlikely to allow oxygen atoms to pass through. Therefore, the shift amount of the threshold voltage of the memory cell MC having the configuration of FIG. 8 is less than the shift amount of the threshold voltage of the memory cell MC having the configuration of FIG. 6.

In the configuration of FIG. 9, both hafnium oxide of the metal oxide 221a_1 and the aluminum oxide film of the block insulating film 221a_2 are provided. However, hafnium oxide of the metal oxide 221a_1 is extremely thin and is barely recognizable as a film. Therefore, the threshold voltage of the memory cell MC having the configuration of FIG. 9 is shifted by an amount larger than a shift amount of the threshold voltage of the memory cell MC having the configuration of FIG. 7 or FIG. 8. However, as hafnium oxide of the metal oxide 221a_1 is provided between the aluminum oxide film of the block insulating film 221a_2 and the cover insulating film 221, the threshold voltage of the memory cell MC having the configuration of FIG. 9 is shifted by an amount less than a shift amount of the threshold voltage of the memory cell MC having the configuration of FIG. 6.

In the configuration of FIG. 10, the stacked film including the cover insulating film 221, the block insulating film 221a_2, and the barrier film 21b is provided between the charge trapping film 222 and the electrode film 21. The metal oxide 221a_1 is not provided. However, the electrode film 21 is made of tungsten, that is less likely to oxidize than molybdenum. Therefore, the shift amount of the threshold voltage of the memory cell MC in FIG. 10 is less than the shift amount of the threshold voltage of any of the memory cells MC in FIGS. 6 to 9. In FIG. 11, the shift amount of the threshold voltage in the configuration of FIG. 10 is set to zero (reference value).

As such, when the electrode film 21 is made of molybdenum, the metal oxide 221a_1 is provided between the charge trapping film 222 and the electrode film 21 instead of or together with the aluminum oxide film of the block insulating film 221a_2. Thereby, the shift amount of the threshold voltage can be reduced and data retention property can be improved. The metal oxide 221a_1 is able to obtain the same effect even when employing a tetravalent metal oxide among any of TiO₂, ZrO₂, HfO₂, and RfO₂.

FIG. 12 is a graph illustrating write saturation voltages. A vertical axis of the graph indicates the write saturation voltage. A horizontal axis indicates each configuration of FIGS. 6 to 10. The write saturation voltage is a maximum value of the threshold voltage when data is written to the memory cell MC. When a write voltage applied to the word line WL is increased, the threshold voltage of the memory cell MC to which data is written also increases. However, when the amount of charge held in the charge trapping film 222 is saturated, the threshold voltage of the memory cell MC does not increase any more even when the write voltage of the word line WL is increased. Therefore, the threshold voltage of the memory cell MC to which data is written has a maximum value. The maximum value of the threshold voltage of the memory cell MC is referred to as “write saturation voltage”. To facilitate data detection, the write saturation voltage is preferably high.

In the configuration of FIG. 6, the aluminum oxide film of the block insulating film 221a_2 allows oxygen to pass through in an annealing process to be described later, oxidizing the interface between the charge trapping film 222 and the cover insulating film 221 and causing defects. Thereby, a large amount of charge can be held at the interface between the charge trapping film 222 and the cover insulating film 221. As a result, the write saturation voltage is relatively high.

In the configuration of FIG. 7, hafnium oxide of the metal oxide 221a_1 is less likely to allow oxygen to pass through in the annealing process, causing less defects at the interface between the charge trapping film 222 and the cover insulating film 221. Therefore, the write saturation voltage of the memory cell MC having the configuration of FIG. 7 is lower than the write saturation voltage of the memory cell MC having the configuration of FIG. 6.

In the configuration of FIG. 8, both hafnium oxide of the metal oxide 221a_1 and the aluminum oxide of the block insulating film 221a_2 are provided. Therefore, similar to the configuration of FIG. 7, oxygen is less likely to be allowed to pass through, and less defects are caused at the interface between the charge trapping film 222 and the cover insulating film 221. Therefore, the write saturation voltage of the memory cell MC having the configuration of FIG. 8 is also lower than the write saturation voltage of the memory cell MC having the configuration of FIG. 6. The write saturation voltage of the memory cell MC having the configuration of FIG. 8 is substantially equal to the write saturation voltage of the memory cell MC having the configuration of FIG. 7.

In the configuration of FIG. 9, both hafnium oxide of the metal oxide 221a_1 and the aluminum oxide of the block insulating film 221a_2 are provided. Therefore, the write saturation voltage of the memory cell MC having the configuration of FIG. 9 is lower than the write saturation voltage of the memory cell MC having the configuration of FIG. 6. However, hafnium oxide of the metal oxide 221a_1 is extremely thin and is barely recognizable as a film. Therefore, the write saturation voltage of the memory cell MC having the configuration of FIG. 9 is higher than the write saturation voltage of the memory cell MC having the configuration of FIG. 7 or FIG. 8.

In the configuration of FIG. 10, the metal oxide 221a_1 is not provided, but the electrode film 21 is made of tungsten. The write saturation voltage of the memory cell MC of FIG. 10 is at the same level as the write saturation voltage of FIG. 6, and is higher than the write saturation voltage of any of the memory cells MC of FIGS. 7 to 9. The reason is that annealing is performed after forming the aluminum oxide film of the metal oxide 221a_2 and before forming the barrier film 21b and the electrode film 21. In the annealing process, the configuration of FIG. 10 is the same as the configuration of FIG. 6. By the annealing process, the charge trapping film 222 is modified and the write saturation voltage is determined. Therefore, the write saturation voltage of the memory cell MC of FIG. 10 is at the same level as the write saturation voltage of FIG. 6.

As such, when the metal oxide 221a_1 is thick, oxygen is less likely to be allowed to pass through the metal oxide 221a_1, and the charge trapping film 222 is not modified by the annealing process. Therefore, when the metal oxide 221a_1 is thick, the write saturation voltage of the memory cell MC decreases. Meanwhile, when the thickness or the concentration of the metal oxide 221a_1 is decreased, oxygen passes through the metal oxide 221a_1 to a certain extent, and the charge trapping film 222 is modified by the annealing process. Therefore, by decreasing the thickness or the concentration of the metal oxide 221a_1, the write saturation voltage of the memory cell MC is increased and improved. The metal oxide 221a_1 is able to obtain same effect even when employing a tetravalent metal oxide other than hafnium oxide (HfO₂), that is, any of TiO₂, ZrO₂, and RfO₂.

According to FIGS. 11 and 12, the data retention property of the memory cell MC can be improved by providing the metal oxide 221a_1 between the cover insulating film 221 and the aluminum oxide film of the block insulating film 221a_2. Meanwhile, when the metal oxide 221a_1 is excessively thick, the write saturation voltage of the memory cell MC decreases. Therefore, the film thickness or the concentration of the metal oxide 221a_1 is preferably thin or low, as in the configuration of FIG. 9. According to the configuration of FIG. 9, both the data retention property and the write saturation voltage can be improved.

FIG. 13 is a cross-sectional view illustrating an example of a configuration in which a metal oxide 221a_3 is added to the configuration of FIG. 6. In the example of FIG. 13, a stacked film including the cover insulating film 221, the block insulating film 221a_2, and the metal oxide 221a_3 is provided between the charge trapping film 222 and the electrode film 21. The configuration of this example is different from the configuration of FIG. 6 in that the metal oxide 221a_3 is provided between the block insulating film 221a_2 and the electrode film 21. The metal oxide 221a_3 may be, for example, a tetravalent metal oxide among any of TiO₂, ZrO₂, HfO₂, and RfO₂, similar to the metal oxide 221a_1. The metal oxide 221a_3 has a thickness of, for example, 1 nm and can be recognized as a film. Other configuration of FIG. 13 may be the same as the configuration of FIG. 6.

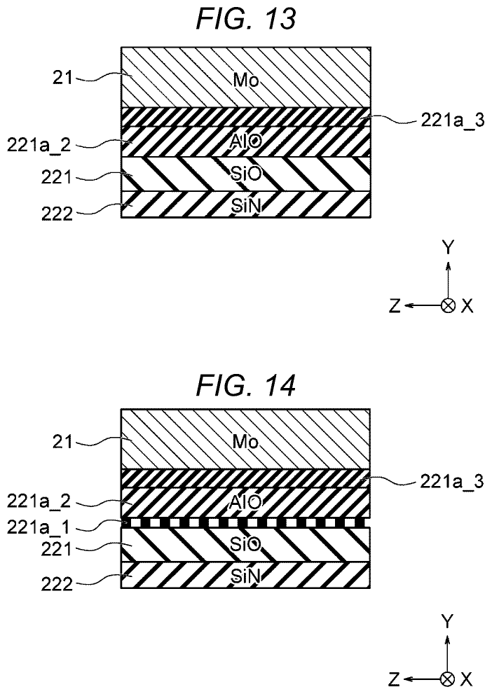

FIG. 14 is a cross-sectional view illustrating an example of a configuration in which the metal oxide 221a_3 is added to the configuration of FIG. 9. In the example of FIG. 14, a stacked film including the cover insulating film 221, the metal oxide 221a_1, the block insulating film 221a_2, and the metal oxide 221a_3 is provided between the charge trapping film 222 and the electrode film 21. The configuration of the present example is different from the configuration of FIG. 9 in that the metal oxide 221a_3 is provided at the interface between the block insulating film 221a_2 and the electrode film 21. Similar to the metal oxide 221a_1, the metal oxide 221a_3 may be, for example, hafnium oxide (HfO₂), and may be another tetravalent metal oxide among any of TiO₂, ZrO₂, HfO₂, and RfO₂. The metal oxide 221a_3 has a thickness of, for example, 1 nm and can be recognized as a film. That is, the metal oxide 221a_1 has a lower concentration or a thinner film thickness than the metal oxide 221a_3. Other configuration of FIG. 14 may be the same as the configuration of FIG. 9.

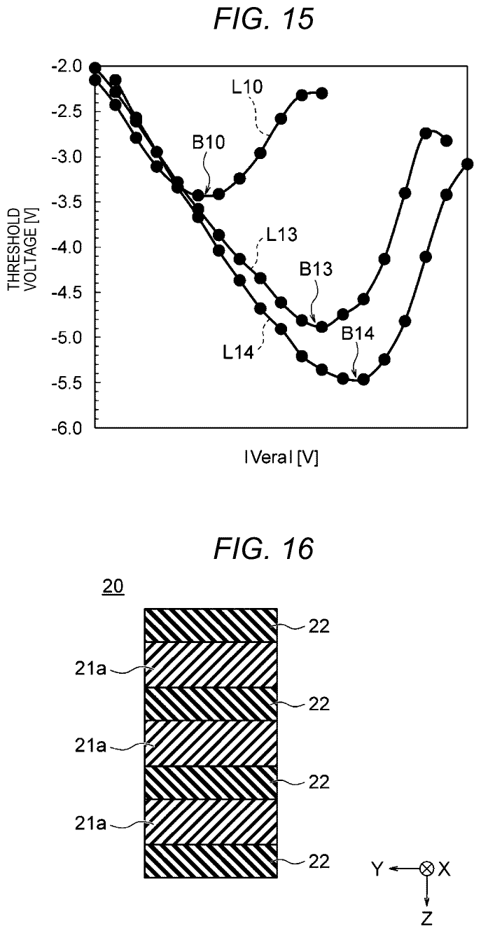

FIG. 15 is a graph illustrating erase saturation voltages. A vertical axis of the graph indicates the threshold voltage of the memory cell MC after erasing (erase voltage). A horizontal axis is a voltage Vera which is applied to the word line WL in the erase operation. The erase saturation voltage is a minimum value of the threshold voltage of the memory cell MC after data has been erased. When an absolute value of the voltage Vera applied to the word line WL is increased (increased toward a negative voltage side), the threshold voltage of the memory cell MC from which data is erased is decreased accordingly. However, when the amount of charge in the charge trapping film 222 is entirely removed, the threshold voltage of the memory cell MC does not decrease any more even when the absolute value of the voltage Vera of the word line WL is further increased. Therefore, the threshold voltage of the memory cell MC from which data is erased has a minimum value (bottom). The minimum value of the threshold voltage of the memory cell MC is referred to as “erase saturation voltage”. To facilitate data detection, the erase saturation voltage is preferably low.

The erase voltage in the configuration of FIG. 10 is shown in the graph indicated by a line L10. Defects having fixed charges are likely to occur at the interface between the silicon oxide film of the cover insulating film 221 and the aluminum oxide film of the block insulating film 221a_2. Therefore, in the erase operation, electrons injected from the electrode film 21 to the charge trapping film 222 are trapped in the defects, and the erase saturation voltage deteriorates. As a result, an erase saturation voltage B10 in the configuration illustrated in FIG. 10 is relatively high.

The erase voltage in the configuration of FIG. 13 is shown in the graph indicated by a line L13. Here, an erase saturation voltage B13 is lower than that of the configuration illustrated in FIG. 10. However, even in the configuration illustrated in FIG. 13, an interface is formed between the silicon oxide film of the cover insulating film 221 and the aluminum oxide film of the block insulating film 221a_2. Therefore, in the erase operation, electrons injected from the electrode film 21 to the charge trapping film 222 are trapped in the defects. Thus, the erase saturation voltage is deteriorated compared to the configuration illustrated in FIG. 14, which is described below.

In contrast, the erase voltage in the configuration of FIG. 14 is shown in the graph indicated by a line L14. Here, an erase saturation voltage B14 is lower by 2 V or more than the erase saturation voltage in the configuration of FIG. 10, and is further lower by about 0.8 V than the erase saturation voltage in the configuration of FIG. 13. The reason is that the metal oxide 221a_1 provided at the interface between the silicon oxide film of the cover insulating film 221 and the aluminum oxide film of the block insulating film 221a_2 prevents occurrence of defects at the interface.

As such, by providing the metal oxides 221a_1 and 221a_3, the erase saturation voltage can be significantly improved. As described with reference to FIG. 12, when the metal oxide 221a_1 is thick, the write saturation voltage deteriorates. Therefore, as described with reference to FIG. 9, the thickness of the metal oxide 221a_1 is preferably thin. Thereby, the write saturation voltage can be increased and the erase saturation voltage can be decreased.

The annealing process of modifying the charge trapping film 222 is performed after the aluminum oxide film of the block insulating film 221a_2 is formed and before the metal oxide 221a_3 is formed. Therefore, the write saturation voltage of the configuration of FIG. 14 is substantially the same as the write saturation voltage of FIG. 9. As a result, the configuration of FIG. 14 is more advantageous than the configuration of FIGS. 7 and 8 in terms of the write saturation voltage.

In the configuration of FIG. 14, as the metal oxide 221a_3 is added to the configuration of FIG. 9, it is apparent that the data retention property is improved compared to the data retention property of the configuration of FIG. 9. Therefore, the configuration of FIG. 14 is preferable similar to or more preferable than the configuration of FIG. 9 considering the data retention property and the write saturation voltage. As a result, the configuration of FIG. 14 may be the most preferable in terms of the data retention property, the write saturation voltage, and the erase saturation voltage. Although the electrode film 21 is made of molybdenum, the same effect can be obtained even when tungsten is employed.

From the above description, the data retention property, the write saturation voltage, and the erase saturation voltage can be improved by providing the metal oxide 221a_1 at the interface between the cover insulating film 221 and the aluminum oxide film of the block insulating film 221a_2 as in the configuration of FIG. 9.

The data retention property and the erase saturation voltage can be further improved by providing the metal oxide 221a_3 between the aluminum oxide film of the block insulating film 221a_2 and the electrode film 21 as in the configuration of FIG. 14.

An operating voltage of the word line WL can be lowered by lowering the erase saturation voltage. Therefore, a breakdown voltage between the electrode films 21 adjacent in the Z direction can be lowered, and the thickness of the insulating film 22 in the Z direction can be reduced. For example, the thickness of the insulating film 22 in the Z direction can be made less than about 40 nm.

Next, a manufacturing method of the semiconductor memory device according to the present embodiment will be described.

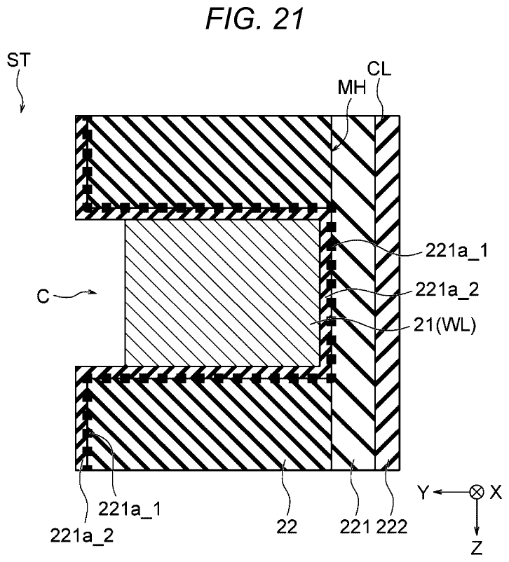

FIGS. 16 to 21 are cross-sectional views each illustrating an example of a manufacturing process of the semiconductor memory device 1 according to the present embodiment.

First, as illustrated in FIG. 16, the stacked body 20 of the array chip 2 is formed by alternately stacking material films 21a and the insulating films 22 in a −Z direction. The material film 21a employs, for example, a silicon nitride film. The insulating film 22 employs, for example, a silicon oxide film.

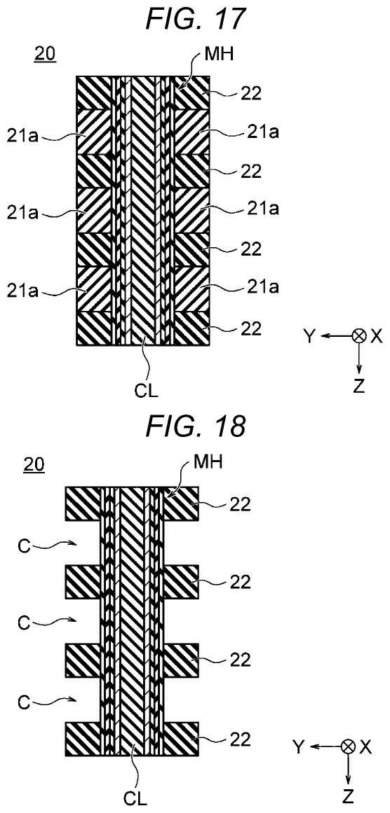

Next, a plurality of memory holes MH penetrating the stacked body 20 in the Z direction are formed using lithography and etching techniques. Next, as illustrated in FIG. 17, the columnar bodies CL are formed in the plurality of memory holes MH. Each columnar body CL is formed by depositing the cover insulating film 221, the charge trapping film 222, the tunnel insulating film 223, and the semiconductor body 210 on a sidewall of the stacked body 20 in the memory hole MH.

Next, the slits ST illustrated in FIG. 2 or FIG. 5 are formed in the stacked body 20 using lithography and etching techniques. The slits ST are provided to penetrate the stacked body 20 in the Z direction.

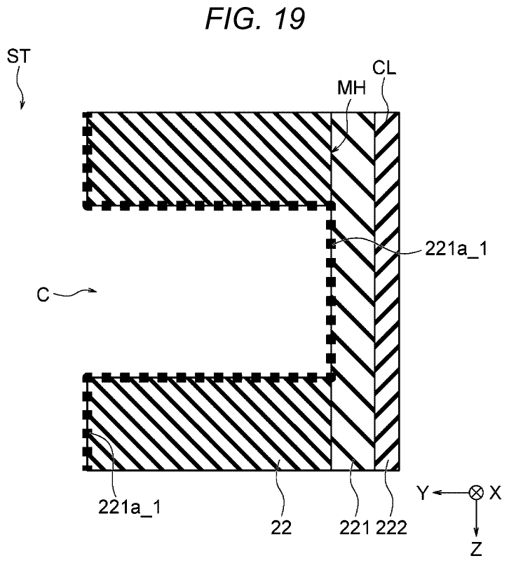

Next, the material film 21a is removed through the slits ST using a wet etching method. Thereby, as illustrated in FIG. 18, spaces C are formed between the insulating films 22 adjacent in the Z direction (at a location where the material film 21a was provided).

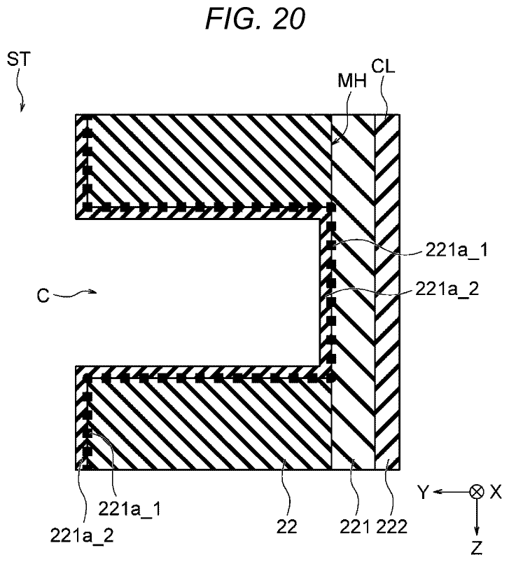

FIGS. 19 to 21 show enlarged cross sections of a part of the space C.

The metal oxide 221a_1 is deposited on the space C and the inner wall of the slit ST through the slit ST using an atomic layer deposition (ALD) method. The metal oxide 221a_1 is introduced onto side surfaces of the columnar bodies CL exposed in the space C and the slits ST and onto surfaces of the insulating films 22. The metal oxide 221a_1 may be, for example, a tetravalent metal oxide among any of TiO₂, ZrO₂, HfO₂, and RfO₂. The metal oxide 221a_1 has a concentration or a thickness (for example, 0.1 nm) that is not recognizable as a film.

Next, the aluminum oxide film of the block insulating film 221a_2 is deposited on the space C and the inner wall of the slit ST through the slit ST using the ALD method. A film thickness of the aluminum oxide film of the block insulating film 221a_2 is, for example, about 2.7 nm.

Next, to modify the charge trapping film 222, the stacked body 20 and the columnar body CL are annealed. An annealing temperature is, for example, 240 degrees to 250 degrees. By the annealing process, oxygen is allowed to pass through the aluminum oxide film of the block insulating film 221a_2 and hafnium oxide of the metal oxide 221a_1. Although hafnium oxide is less likely to allow oxygen to pass through than the aluminum oxide film, as hafnium oxide is thin enough not to be recognizable as a film, oxygen can pass through the metal oxide 221a_1. Thereby, oxygen oxidizes the interface between the charge trapping film 222 and the cover insulating film 221 and causes defects. As a result, the write saturation voltage can be increased.

The concentration of the metal oxide 221a_1 is maximum at the interface between the cover insulating film 221 and the block insulating film 221a_2. By the annealing process, the metal oxide 221a_1 diffuses from the interface between the block insulating film 221a_2 and the cover insulating film 221 and the interface between the block insulating film 221a_2 and the insulating film 22. The metal oxide 221a_1 diffuses in a range of, for example, 0.1 nm to 0.3 nm from the interface between the block insulating film 221a_2 and the cover insulating film 221 or the insulating film 22. The metal oxide 221a_1 may be provided as a film, or may be detected as a component while not being recognized as a film.

Next, as illustrated in FIG. 21, a metal material such as molybdenum or tungsten is deposited on the inner wall of the space C as the material of the electrode film 21.

Next, an insulating film 101 such as a silicon oxide film is formed on the inner wall of the slit ST.

Next, a metal film such as molybdenum or tungsten is embedded inside the insulating film 101 in the slit ST. Thereby, a source wiring LI is formed in the slit ST illustrated in FIG. 5, obtaining the structure illustrated in FIG. 3.

Thereafter, contacts and multilayer wiring layers are formed, and the semiconductor memory device 1 according to the present embodiment is completed. Here, the structure illustrated in FIG. 9 is obtained.

To form the structure illustrated in FIG. 14, the aluminum oxide film of the block insulating film 221a_2 is formed, an annealing process is performed, and then the metal oxide 221a_3 is deposited on the inner wall of the space C and the slit ST through the slit ST using the ALD method or the like. The metal oxide 221a_3 is formed on the aluminum oxide film of the block insulating film 221a_2 in the space C and the slit ST. The metal oxide 221a_3 may be, for example, a tetravalent metal oxide among any of TiO₂, ZrO₂, HfO₂, and RfO₂, similar to the metal oxide 221a_1. Then, the electrode film 21 is formed and the structure illustrated in FIG. 14 is obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body in which a plurality of electrode films and a plurality of first insulating films are alternately stacked in a first direction;
a columnar body that penetrates the stacked body in the first direction;
an aluminum oxide film provided between the columnar body and each of the electrode films; and
a first tetravalent metal oxide provided at an interface between the columnar body and the aluminum oxide film.

2. The semiconductor memory device according to claim 1, wherein
the columnar body includes
a semiconductor layer that penetrates the stacked body in the first direction,
a second insulating film provided between the semiconductor layer and the stacked body,
a third insulating film provided between the second insulating film and the semiconductor layer, and
a fourth insulating film provided between the third insulating film and the semiconductor layer, and
the first tetravalent metal oxide is provided at an interface between the aluminum oxide film and the second insulating film.

3. The semiconductor memory device according to claim 2, wherein a concentration of the first tetravalent metal oxide is maximum at the interface between the aluminum oxide film and the second insulating film.

4. The semiconductor memory device according to claim 3, wherein the concentration of the first tetravalent metal oxide decreases from the interface between the aluminum oxide film and the second insulating film toward the stacked body.

5. The semiconductor memory device according to claim 2, wherein the first tetravalent metal oxide has a thickness in a range of 0.1 nm to 0.3 nm in a second direction intersecting the interface between the aluminum oxide film and the second insulating film.

6. The semiconductor memory device according to claim 5, wherein the thickness of the first tetravalent metal oxide is less than the thickness of the aluminum oxide film.

7. The semiconductor memory device according to claim 1, further comprising a second tetravalent metal oxide provided at an interface between the aluminum oxide film and each of the electrode films.

8. The semiconductor memory device according to claim 1, wherein the first tetravalent metal oxide is one of TiO₂, ZrO₂, HfO₂, and RfO₂.

9. A semiconductor memory device comprising:
a stacked body in which a plurality of electrode films and a plurality of first insulating films are alternately stacked in a first direction;
a columnar body provided to penetrate the stacked body in the first direction;
an aluminum oxide film provided between the columnar body and each of the electrode films; and
a first tetravalent metal oxide having a thickness of 1 nm or less, provided at an interface between the columnar body and the aluminum oxide film.

10. The semiconductor memory device according to claim 9, wherein
the columnar body includes
a semiconductor layer that penetrates the stacked body in the first direction,
a tunnel insulating film in contact with and surrounding the semiconductor layer,
a charge trapping film in contact with and surrounding the tunnel insulating film, and
a cover insulating film in contact with and surrounding the charge trapping film, and
the first tetravalent metal oxide is provided at an interface between the aluminum oxide film and the cover insulating film.

11. The semiconductor memory device according to claim 10, wherein a concentration of the first tetravalent metal oxide is maximum at the interface between the aluminum oxide film and the cover insulating film.

12. The semiconductor memory device according to claim 11, wherein the concentration of the first tetravalent metal oxide is greater at positions that are closer to the interface than those that are farther from the interface.

13. The semiconductor memory device according to claim 9, wherein the thickness of the first tetravalent metal oxide is in a range of 0.1 nm to 0.3 nm.

14. The semiconductor memory device according to claim 13, wherein the thickness of the first tetravalent metal oxide is less than the thickness of the aluminum oxide film.

15. The semiconductor memory device according to claim 9, further comprising a second tetravalent metal oxide provided at an interface between the aluminum oxide film and each of the electrode films.

16. The semiconductor memory device according to claim 9, wherein the first tetravalent metal oxide is one of TiO₂, ZrO₂, HfO₂, and RfO₂.

17. A manufacturing method of a semiconductor memory device, the method comprising:
forming a stacked body by stacking a plurality of sacrificial films and a plurality of first insulating films alternately in a first direction;
forming a columnar body penetrating the stacked body in the first direction;
removing the plurality of sacrificial films;
introducing a first tetravalent metal oxide to a side surface of the columnar body exposed by removing the plurality of material films;
forming an aluminum oxide film on the side surface of the columnar body;
heat-treating the stacked body; and
forming electrode films in spaces formed by removing the plurality of sacrificial films.

18. The method according to claim 17, wherein the first tetravalent metal oxide is formed to have a thickness in a range of 0.1 nm to 0.3 nm.

19. The method according to claim 18, wherein the first tetravalent metal oxide is one of TiO₂, ZrO₂, HfO₂, and RfO₂.

20. The method according to claim 17, further comprising:
forming a second tetravalent metal oxide at an interface between the aluminum oxide film and each of the electrode films.
